(19) United States
(12) Patent Application Publication
(10) Pub. No.: US 2016/0032450 A1
(43) Pub. Date: Feb. 4, 2016

(54) METHOD FOR A DIAMOND VAPOR DEPOSITION

(71) Applicant: NEOCOAT SA, La Chaux-de-Fonds (CH)

(72) Inventors: David Rats, Neuchâtel (CH); Christophe Provent, Cessy (FR)

(73) Assignee: NEOCOAT SA, La Chaux-de-Fonds (CH)

(21) Appl. No.: 14/779,488

(22) PCT Filed: Feb. 25, 2014
(86) PCT No.: PCT/EP2014/053658

§ 371 Date: Sep. 23, 2015

(30) Foreign Application Priority Data
Mar. 28, 2013 (EP) 13161778.9

(51) Int. Cl. C23C 16/27; B81C 1/00; H01L 21/02; H01J 37/32; C01B 31/06

(52) U.S. Cl. CPC C23C 16/274; H01J 37/32403; C01B 31/06; H01L 21/02115; H01L 21/02274; B81C 1/00373; H01J 2237/327; H01J 2237/3321; H01J 2237/3323

(57) ABSTRACT

The present invention relates to a method for depositing nanocrystalline diamond using a diamond vapor deposition facility which includes: a vacuum reactor including a reaction chamber connected to a vacuum source; a plurality of plasma sources arranged along a matrix that is at least two-dimensional in the reaction chamber; and a substrate holder arranged in the reactor, said method being characterized in that the deposition is carried out at a temperature of 100 to 500° C.

### TECHNICAL FIELD

The present invention relates to the field of depositing diamond on a substrate, in particular to the vapor deposition of nanocrystalline diamond. “Nanocrystalline diamond” refers to a polycrystalline diamond, having a grain size comprised between 1 and 50 nm, typically around 10 nm, making it possible to obtain an average roughness of less than 100 nm, preferably less than 20 nm.

### STATE OF THE ART

Diamond is a material with exceptional properties, such as its considerable hardness, its high Young's modulus or its high heat conductivity. It is possible to synthesize it in a thin layer by chemical vapor deposition (CVD) activating a gas mixture containing at least one carbon precursor and hydrogen, thermally or by plasma. Activating the gas phase makes it possible to generate radical species such as atomic hydrogen or the methyl radical with sufficient concentration to ensure fast growth of a diamond layer with great crystalline quality.

With the techniques generally used, it is possible to obtain polycrystalline diamond with a grain size of the order of one micron for a thickness of less than ten microns. This large grain size entails an average surface roughness of more than 100 nm, making its use impossible for tribological or integration applications in electronic components or microsystems (MEMS).

This is for example the case with thermal activation of the reaction gas by a hot filament (HFCVD for Hot Filament Chemical Vapor Deposition). This technique allows deposits over large surfaces (>0.5 m²), but with grains whose size, of the order of one micron, is not satisfactory. Further, the deposition temperature is much greater than 400° C., usually above 750° C. Therefore, when the substrate is cooled after the deposition, it undergoes thermal deformations according to a coefficient different from that of diamond. Differential deformation frequently entails stresses or defects at the diamond layer or at the interface with the diamond layer.

In order to obtain smooth deposits, post-treatment such as polishing is possible, but it is expensive and not very adapted to parts with a complex geometry, i.e., parts having raised/recessed portions relative to a reference plane, or three-dimensional parts. A complex part is a part on which a diamond deposit produces a layer with a non-planar surface (the roughness of the deposit is not important here). In other words, the surface of the diamond layer, i.e., the layer without taking its own thickness into account, is three-dimensional.

Another solution is to deposit a nanocrystalline diamond layer diamond layer by promoting continuous nucleation during the deposition. The obtained diamond may have a grain size of the order of tens of nanometers and an average roughness of less than 20 nanometers. For this purpose, the conventional plasma microwave technology allows deposition of nanocrystalline diamond of good quality, but on small surfaces (<0.05 m²) and at temperatures above 400° C. (usually >600° C.), causing thermal stresses similar to those mentioned above.

Both aforementioned techniques use working pressures of more than 10 mbar, generating convection phenomena that are not very favorable for diffusing radical species in small spaces.

In order to be able to treat parts on an industrial scale, a deposition surface of more than 0.1 m² is required in order to obtain a limited treatment cost.

Further, in order to have a uniform deposition on parts structured in the bulk or that are entirely open, it is important for the radical species to be able to be transported in smaller spaces with a low recombination probability (need for a long enough lifetime).

Finally, in order to be able to deposit a nanocrystalline diamond layer without altering the intrinsic properties of the material to be coated or its geometrical tolerances, it is important to deposit it at a low temperature in order to minimize thermal deformations and stresses resulting from a different thermal behavior between the diamond and the substrate.

The use of a plasma technology with coupling of microwave energy through surface waves is known, which makes it possible to reduce the deposition temperature to a value close to 100° C. However, known devices do not allow easy application of a regular diamond layer on a substrate with a complex shape.

The present invention aims to resolve these problems.

### BRIEF DESCRIPTION OF THE INVENTION

More specifically, the invention relates to a diamond deposition method and to a part obtained according to this method, as mentioned in the claims.

### BRIEF DESCRIPTION OF THE DRAWINGS

Other details of the invention will become more clearly apparent upon reading the description which follows, done in reference to the appended drawing, wherein:

FIG. 1 is a view illustrating a piece of diamond deposition equipment advantageously used in the method according to the invention,

FIGS. 2, 3, 4 and 5 give illustrations of substrates which may advantageously be covered with diamond using the method according to the invention, and

FIGS. 6 and 7 respectively show a non-compliant deposit as obtained with the techniques of the state of art and a compliant deposit obtained with the present invention.

### DETAILED DESCRIPTION OF THE INVENTION

As mentioned above, nanocrystalline diamond deposits may be done by applying the plasma chemical vapor deposition technique, on various substrates, which will be defined hereinafter. However, the pieces of equipment of the state of the art did not make it possible to perform deposits on substrates with a complex shape. A substrate with a complex shape is defined as a substrate having raised/recessed portions, i.e., recessed or protruding, relative to a reference plane, or three-dimensional parts. Thus, a diamond deposit on such a part produces a non-planar layer, i.e., vectors normal to the surface of the deposit are not all parallel to each other. In other words, the surface of the diamond layer, i.e., the layer without taking its own thickness into account, is three-dimensional.

For example, FIGS. 6a and 6b illustrate a deposit obtained using techniques of the prior art. In FIG. 6a, the reaction gas mixture is seen, symbolized by dots, which attempts to penetrate the structures of the substrate, but without managing to be distributed homogeneously, in particular in the bottom of the structures, and especially if the latter are deep and narrow. In FIG. 6b, the thick lines represent the diamond deposit. It may be seen that that it is not uniform over the whole surface of the substrate, in particular in the bottom of the structures.

According to the invention, these deposits on this kind of substrate are produced by applying microwave plasma deposition technology by using a matrix of point-like plasma sources (MEPS, for Matrix Elementary Plasma Source) with equipment as proposed in FIG. 1.

This deposition system includes a vacuum reactor 3, a substrate holder 5 and a surface-wave plasma source, here coaxial applicators 6 arranged in a three-dimensional matrix, in the wall of the vacuum reactor 3. It may be noted that, if the intention is to produce a deposit on a planar surface, the applicators may also be positioned in a two-dimensional matrix. Preferably, the coaxial applicators each have, at their end located in the reaction chamber, a quartz or alumina window, defining an active area located in the reaction chamber. This type of applicator is commercially available and does not need to be described in detail.

Preferably, the matrix makes it possible to have a homogeneous and qualitative deposit with a number of plasma sources per square meter comprised between 80 and 320. As an example, it is possible to have about 8 to 32 sources for a plasma surface area of 0.1 m², which substantially corresponds to a substrate holder of 300×300 mm². The plasma surface area is defined as being the surface area formed by the plasma provided by the different sources. This surface area may vary depending on the shape of the plasma and its curvature, which is itself adapted according to the surface to be coated.

Owing to the use of a matrix of point-like plasma sources, it is possible to lower the working pressure to a value of less than 1 mbar, preferably comprised between 0.1 and 1 mbar. Such a pressure makes it possible to promote diffusion phenomena of chemical species, and therefore have very homogeneous deposits in the raised/recessed portions of the substrate and, if necessary, on the flanks of its structures, without altering the properties of the diamond.

It is also possible to operate at a temperature comprised between 100° C. and 500° C., which makes it possible to limit the thermal deformations of the substrate, in particular with a metal substrate. Thus, during the cooling of the coated substrate, the deformation difference between the substrate and the diamond layer is reduced, which limits the mechanical stresses at the interface of the materials accordingly, without having to resort to intermediate layers.

Another advantage of this deposition technique with a matrix of point-like plasma sources is that there is no physical limitation on the number of coaxial applicators or of apertures in the waveguide or in the reactor, thereby making it possible to obtain a very large effective deposition surface.

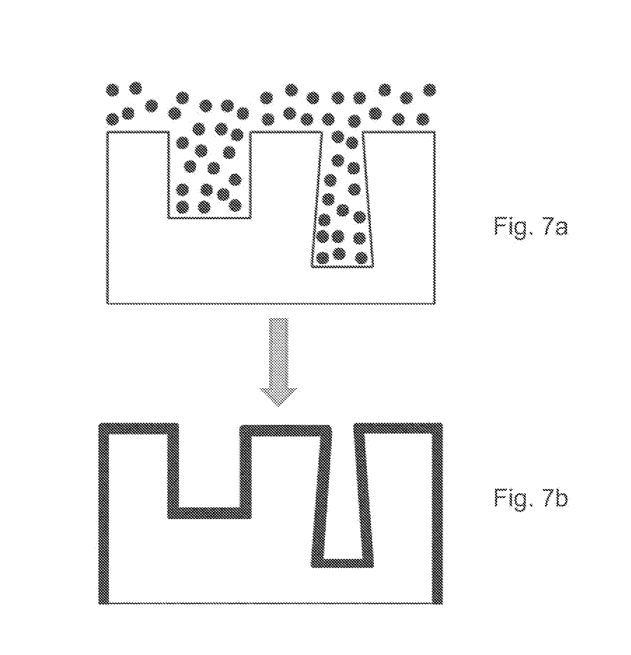

FIG. 7a shows that owing to the reaction conditions, the reaction gas mixture, symbolized by dots, manages to penetrate the structures of the substrate and is homogeneously distributed, particularly in the bottom of the structures, even if the latter are deep and narrow. In FIG. 7b, the thick lines represent the diamond deposit. It may be seen that the deposit is uniform over the entire surface of the substrate, including in the bottom of the structures, unlike what was observed in FIG. 6b.

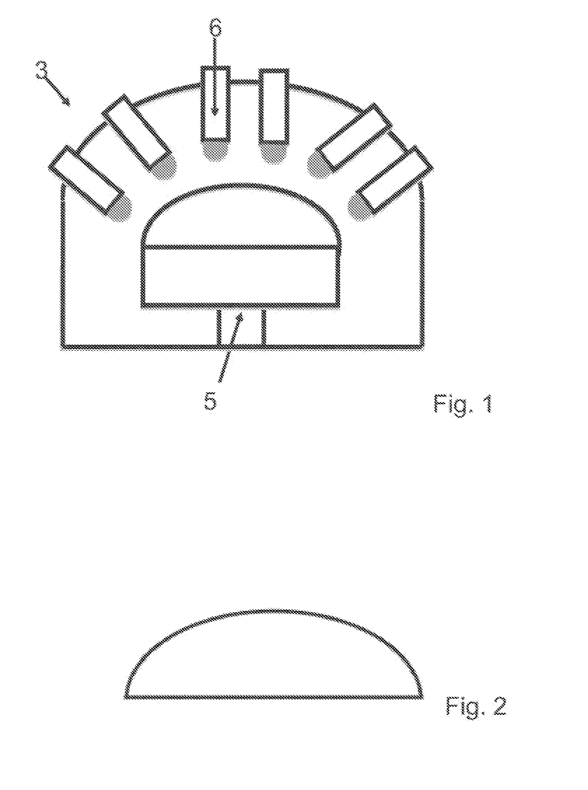

By using this installation, it is thus possible to carry out a nanocrystalline diamond deposition on a complex part, as proposed in FIG. 2, having a convex surface. Naturally, deposition on a concave surface is also possible. Such a part may be made from a material selected from the following materials: silicon and silicon-based compounds, diamond, refractory metals and derivatives, transition metals and derivatives, stainless steels, titanium-based alloys, superalloys, cemented carbides, polymers, ceramics, glasses, oxides (molten silica, alumina), semiconductors of columns III-V or II-VI of the Periodic Classification. The part to be deposited may also include a base made from any material, coated with a thin layer of the aforementioned materials, which defines the substrate for the diamond deposition. Such a part may also consist of an assembly of several materials forming a heterogeneous surface (microprocessor, MEMS, MOEMS, sensors, etc.).

According to a particular example, the substrate as illustrated in FIG. 2 is made from a steel of grade 316L, with a hemispherical shape, exclusively sown with a method of the state of the art and without any additional pre-treatment or preliminary deposition of an intermediate layer, such as a diffusion barrier.

A 200 nm nanocrystalline diamond layer was deposited by using a chemical vapor deposition method assisted with a matrix of point-like plasma sources using an installation as described above with the following deposition conditions:
Temperature of the substrate=300° C.,
Working pressure=0.5 mbar.

The color of the deposit is pale pink-green. A verification of the thickness of the deposited layer (measured by UV-VIS reflectometry) and the quality of the deposit (measurement by Raman spectrometry) shows that the variation in uniformity (calculated using the formula=(min-max)/average) is less than 10% over the whole deposited surface.

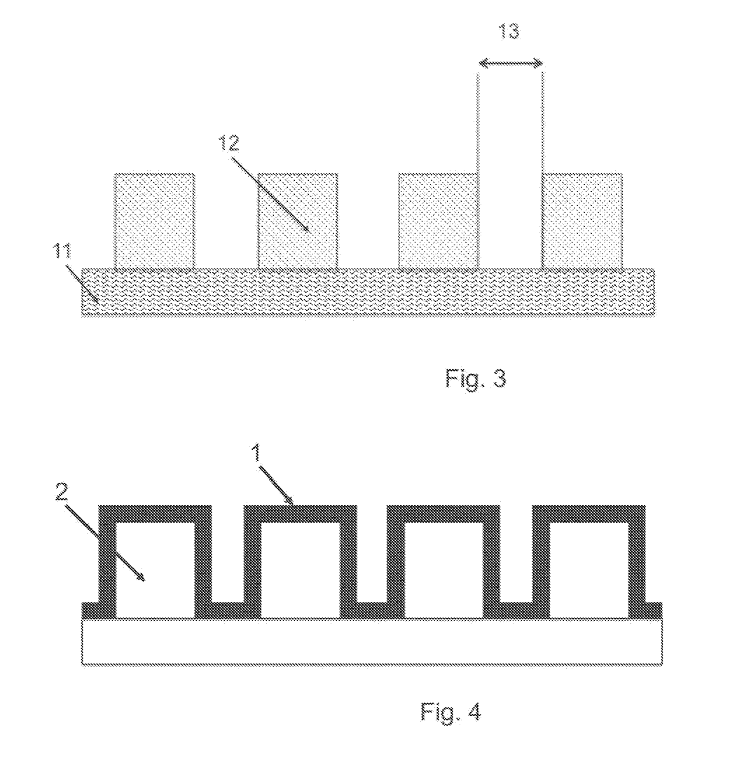

It is also possible to carry out nanocrystalline diamond deposition on a structured part, as proposed in FIG. 3. Using an installation of the type described above, it is possible to produce a coating over all of its active faces with great homogeneity in terms of thickness and quality, as diagrammatically shown in FIG. 4.

According to a second example, a deposition was carried out on a structured part, as proposed in FIG. 3. Such a part may be made from a material selected from the following materials: silicon and silicon-based compounds, diamond, refractory metals and derivatives, transition metals and derivatives, stainless steels, titanium-based alloys, superalloys, cemented carbides, polymers, ceramics, glasses, oxides (molten silica, alumina), semiconductors of columns III-V or II-VI of the Periodic Classification. As above, the part to be deposited may also include a base made from any material, coated with a thin film of the aforementioned materials, which defines the substrate for the diamond deposition. Such a part may also consist of an assembly of several materials forming a heterogeneous surface (microprocessor, MEMS, MOEMS, sensors, etc.).

More particularly, on a single-crystal silicon wafer with a diameter of 200 mm and a thickness 11 of 1 mm, square structures 12 with a side of 1 mm and with a thickness of 0.1 mm were manufactured by a photolithographic and plasma etching method, by making a space 13 between two consecutive structures of about 0.1 mm.

A 200 nm nanocrystalline diamond layer was deposited by using the chemical vapor deposition method using a matrix of point-like plasma sources by means of a facility as described above and with the following deposition conditions:
Temperature of the substrate=300° C.,
Working pressure=0.5 mbar.

A verification of the thickness of the deposited layer (measurement of a section with a scanning electron microscope) and the quality of the deposit (measurement by Raman spectrometry) shows that the variation in uniformity (calculated using the formula =(min-max)/average) is less than 10% over the whole thickness of the structure.

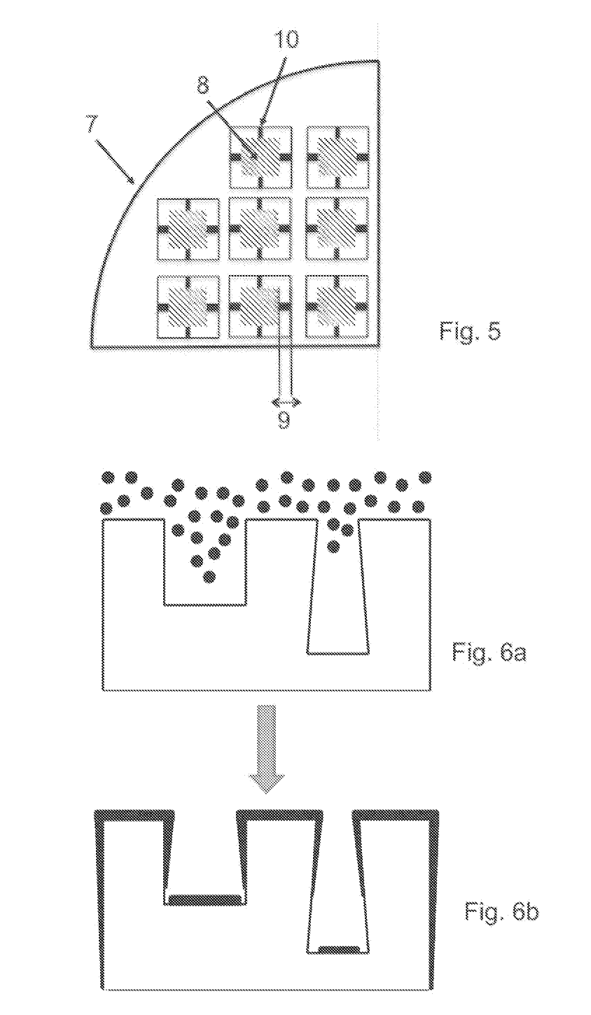

In FIG. 5, an additional example is illustrated, wherein a structured substrate including apertures over its entire length or in the bulk of the substrate, is covered with a nanocrystalline diamond layer. More specifically, on a single-crystal silicon wafer with a diameter of 100 mm and a thickness 7 of 0.5 mm, square structures 8 with a side of 10 mm were cut out, typically with a laser method, by making a space 9 between the structure and the support, the size of which is typically comprised between 0.05 and 0.5 mm. Each structure is maintained by four beams substantially 0.1 mm wide.

A 200 nm nanocrystalline diamond layer was deposited using the chemical vapor deposition method via a matrix of point-like plasma sources by means of an installation as described above, with the following deposition conditions:
Temperature of the substrate=300° C.,
Working pressure=0.5 mbar.

A verification of the thickness of the deposited layer (measurement of a section with a scanning electron microscope) and the quality of the deposit (measurement by Raman spectrometry) shows that the variation in uniformity (calculated using the formula=(min-max)/average) is less than 10% over the whole thickness of the structure.

A deposition was also done on a disk-shaped substrate made from a titanium-based alloy, Ti-4Al-6V (diameter=100 mm and thickness=2 mm) exclusively sown using a method of the state of the art and without any additional pretreatment or preliminary deposition of an intermediate layer, such as a diffusion barrier.

A 300 nm nanocrystalline diamond layer was deposited using the chemical vapor deposition method using a matrix of point-like plasma sources by applying an installation as described above, with the following deposition conditions:
Temperature of the substrate=300° C.,
Working pressure=0.5 mbar.

The color of the deposit is pale pink. A verification of the thickness of the deposited layer (measured by UV-VIS reflectometry) and the quality of the deposit (measurement by Raman spectrometry) shows that the variation in uniformity (calculated using the formula=(min-max)/average) is less than 10% over the whole deposited surface.

Thus, as a direct consequence of the application of the chemical vapor deposition method according to the invention using a matrix of point-like plasma sources by means of an installation as proposed above, a nanocrystalline diamond layer may be made with a thickness comprised between 50 nm and several micrometers, typically down to 10 μm, depending on the duration of the deposition. As compared with diamond-coated parts, obtained by conventional methods, a part obtained with the method according to the invention may be recognized by the fact that the variation in uniformity (calculated using the formula=(min-max)/average) is less than 10% over the whole deposited surface, and also by the fact that the grain size is comprised between 1 and 50 nm, typically around 10 nm, making it possible to obtain an average roughness of less than 100 nm, preferably less than 20 nm. Such depositions may be carried out on surface areas of more than 0.1 m².

1. A nanocrystalline diamond deposition method implementing a piece of chemical vapor diamond deposition equipment comprising
a vacuum reactor comprising a reaction chamber connected to a vacuum source,
a plurality of plasma sources, positioned according to an at least two-dimensional matrix in the reaction chamber, and
a substrate-holder positioned in the reactor, said method comprising:
carrying out said deposition at a temperature comprised between 100 and 500° C. and at a pressure comprised between 0.1 and 1 mbar.

2. (canceled)

3. The deposition method according to claim 1, which is achieved on a substrate having a three-dimensional surface.

4. The deposition method according to claim 3, wherein the substrate has raised/recessed elements, either recessed or protruding, on a surface defining a reference plane.

5. The deposition method according to claim 3, wherein the substrate has a concave or convex surface.

6. The method according to claim 4, wherein the substrate is selected from the group of materials consisting of silicon and silicon-based compounds, diamond, refractory metals and derivatives, transition metals and derivatives, stainless steels, titanium-based alloys, superalloys, cemented carbides, polymers, ceramics, glasses, oxides of the molten silica, alumina type, and semiconductors of columns III-V or II-VI of the Periodic Classification.

7. The method according to claim 6, wherein the substrate is coated with a base made from a material different from the substrate.

8. The method according to claim 6, wherein the substrate has a heterogeneous surface, formed with several materials.

9. A part obtained using the method according to claim 1.

10. The part according to claim 9, including a nanocrystalline diamond layer having a thickness, the value of which is comprised between 50 nm and 10 μm and for which the variation in uniformity, calculated using the formula=(min-max)/average, is less than 10% over the whole deposited surface, the nanocrystalline diamond deposit having a grain size comprised between 1 and 50 nm, with an average roughness of less than 100 nm.

11. The method according to claim 5, wherein the substrate is selected from the group consisting of silicon and silicon-based compounds, diamond, refractory metals and derivatives, transition metals and derivatives, stainless steels, titanium-based alloys, superalloys, cemented carbides, polymers, ceramics, glasses, oxides of the molten silica, alumina type, and semiconductors of columns III-V or II-VI of the Periodic Classification.

12. The method according to claim 11, wherein the substrate is coated with a base made from a material different from the substrate.

13. The method according to claim 11, wherein the substrate has a heterogeneous surface, formed with several materials.

14. The method according to claim 10, wherein the nanocrystalline diamond deposit has a grain size of around 10 nm.

15. The method according to claim 10, wherein the nanocrystalline diamond deposit has an average roughness of less than 20 nm.
